(19) United States
(12) Patent Application Publication
(10) Pub. No.: US 2008/0029778 A1
(43) Pub. Date: Feb. 7, 2008

(54) LED module and method of manufacturing the same

(75) Inventors: Hyung-kun Kim, Yongin-si (KR); Jae-hee Cho, Yongin-si (KR); Yu-sik Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/806,906

(22) Filed: Jun. 5, 2007

(30) Foreign Application Priority Data
Aug. 4, 2006 (KR) 10-2006-0073769

(51) Int. Cl. H01L 33/00; H01L 21/00

(52) U.S. Cl. 257/98; 438/7; 257/E33.061

(57) ABSTRACT

Provided are a light emitting diode (LED) module and a method of manufacturing the same. The LED module may include a package housing including an inner space, a light-emitting chip in the inner space of the package housing, a phosphor layer including a fluorescent material and converting light emitted from the light-emitting chip to light having a longer wavelength than that of the light emitted from the light-emitting chip. The concentration of the fluorescent material of the phosphor layer may be inhomogeneous. The method of manufacturing the LED module may include providing or forming a package housing having an inner space and including a light-emitting chip in the inner space, measuring a radiation pattern of light emitted from the light-emitting chip, and forming a phosphor layer including a fluorescent material on the light-emitting chip and having characteristics that may be determined according to the radiation pattern.

### PRIORITY STATEMENT

This application claims priority under 35 USC §119 to Korean Patent Application No. 2006-0073769, filed on Aug. 4, 2006, in the Korean Intellectual Property Office (KIPO), the entire contents of which is incorporated herein incorporated by reference.

### BACKGROUND

1. Field

Example embodiments relate to a light emitting diode (LED) module having an improved structure that may increase the brightness of light emitted from the LED module, and a method of manufacturing the same.

2. Description of Related Art

A light emitting diode (LED) may include a light-emitting source formed of compound semiconductors (e.g., GaAs, AlGaN, and AlGaAs) to generate various colors of light. LEDs may be easier to manufacture and control than semiconductor lasers, and may have longer lifetimes than fluorescent lamps. As such, LEDs have replaced fluorescent lamps as the illumination light sources of the next generation display devices. Because of the recent development of higher efficiency red, blue, green, and white light emitting diodes formed of nitride materials having improved physical and chemical characteristics, the application of light emitting diodes has expanded.

LED modules formed of phosphor material may produce white light or other colors of light according to the principle that light emitted from blue or ultraviolet light emitting diodes and incident on the phosphor material transmits energy to the phosphor material. Thus, light with a longer wavelength than the incident light may be emitted. For example, in a white light emitting diode module, the phosphor layer may comprise red, green, and blue phosphor material. Photons of ultraviolet light emitted from the LED chip may excite the phosphor layer. Thus, a combination of red, green, and blue light may be emitted from the excited phosphor layer. This combination of visible light may appear as white light to human eyes.

The intensity of radiation of light emitted from the LED to the phosphor layer may vary according to various portions of the phosphor layer. On the other hand, the thickness of the phosphor layer may be uniform. When the phosphor layer is formed to have a uniform thickness without considering the radiation pattern of light emitted from the LED, the phosphor conversion efficiency (PCE), or lighting efficiency, may deteriorate.

### SUMMARY

Example embodiments provide a light emitting diode (LED) module having improved light emitting efficiency and a method of manufacturing the same by determining characteristics of the phosphor layer according to the radiation pattern of light emitted from the light-emitting chip.

According to example embodiments, a LED module may comprise a package housing including an inner space, a light-emitting chip in the inner space of the package housing, and a phosphor layer including a fluorescent material and converting light emitted from the light-emitting chip to light having a longer wavelength than that of the light emitted from the light-emitting chip. The concentration of the fluorescent material of the phosphor layer may be inhomogeneous.

According to example embodiments, a method of manufacturing a LED module may comprise providing or forming a package housing having an inner space and including a light-emitting chip in the inner space, measuring a radiation pattern of light emitted from the light-emitting chip in the inner space of the package housing, and forming a phosphor layer including a fluorescent material on the light-emitting chip and having characteristics that may be determined according to the radiation pattern.

### BRIEF DESCRIPTION OF THE DRAWINGS

Example embodiments will be more clearly understood from the following detailed description taken in conjunction with the accompanying drawings. FIGS. 1-12 represent non-limiting, example embodiments as described herein.

FIG. 1 is a cross-sectional view illustrating a light emitting diode (LED) module according to example embodiments;

FIG. 2 is a graph of the radiation pattern of light emitted from a light-emitting chip of the LED module of FIG. 1 according to example embodiments;

FIGS. 3A through 3C illustrate a method of determining the concentration of fluorescent material and the thickness of the phosphor layer when the light-emitting chip emits light having the radiation pattern of FIG. 2 according to example embodiments;

FIG. 4 is a graph of the radiation pattern of light emitted from a light-emitting chip according to example embodiments;

FIGS. 5A through 5C illustrate a method of determining the concentration of the fluorescent material and the thickness of the phosphor layer when the light-emitting chip emits light having the radiation pattern of FIG. 4 according to example embodiments;

FIG. 6 is a graph illustrating phosphor conversion efficiency (PCE) according to the concentration of the fluorescent material according to example embodiments;

FIG. 7 is a graph illustrating the luminous efficiency according to the thickness of the phosphor layer according to example embodiments;

FIG. 8 is a cross-sectional view illustrating a LED module when the radiation pattern of a light-emitting chip is measured according to example embodiments;

FIG. 9 is a graph illustrating the radiation pattern of a light-emitting chip according to example embodiments;

FIG. 10 is a cross-sectional view of a LED module manufactured by coating a phosphor layer having a varying thickness based on the radiation pattern of FIG. 9 according to example embodiments;

FIG. 11 is a cross-sectional view of a comparative LED module for comparison to a LED module of example embodiments; and

FIG. 12 is a graph comparing the characteristics of the LED module of FIG. 10 to that of the LED module of FIG. 11.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

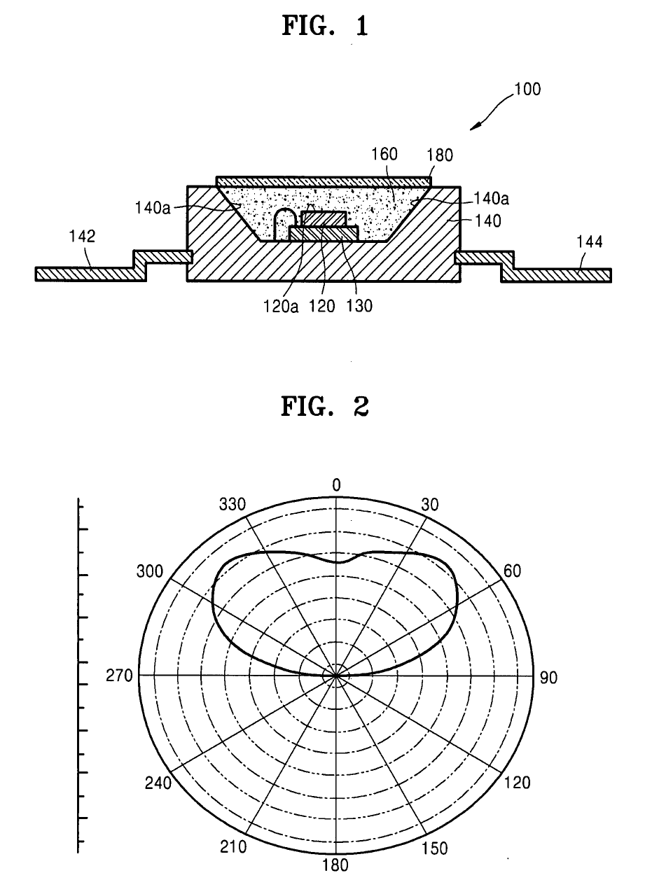

FIG. 1 is a cross-sectional view illustrating a light emitting diode (LED) module 100 according to example embodiments.

Referring to FIG. 1, the LED module 100 may include a light-emitting chip 120, and a phosphor layer 180 including a fluorescent material and converting light emitted from the light-emitting chip 120 into light having a longer wavelength than that of the light emitted from the light-emitting chip 120.

The light-emitting chip 120 may be formed in the inner space of a package housing 140. The light-emitting chip 120 may be on a submount 130 formed on the bottom surface of the inner space of the package housing 140. The package housing 140 may include the inner reflective surface 140a which may reflect light emitted from the light-emitting chip 120 towards the phosphor layer 180. The size of the package housing 140 may be determined based on the usage of the LED module 100. A first lead frame 142 and a second lead frame 144 may be formed on the lower portion of the package housing 140. The first lead frame 142 and the second lead frame 144 may be electrically connected to n and p electrodes (not shown) of the light-emitting chip 120, respectively. A voltage may be applied between the n and p electrodes such that the light-emitting chip 120 is able to emit light. The light-emitting chip 120 may include a p-type semiconductor layer, an active layer, and an n-type semiconductor layer. Because the structure of the light-emitting chip 120 may be known to those of ordinary skill in the art, a detailed description of the light-emitting chip 120 is omitted.

The inner space of the package housing 140 may be filled with a resin layer 160 surrounding the light-emitting chip 120 and the submount 130. The resin layer 160 may protect the light-emitting chip 120 and may reduce the difference of the refractive indices of the light-emitting chip 120 and the outside of the light-emitting chip 120. The more similar the refractive index of the resin layer 160 is to the refractive index of the light-emitting chip 120, the lesser the amount of light that may be reflected at the interface surface 120a between the light-emitting chip 120 and the resin layer 160 when light is emitted from the light-emitting chip 120 to the resin layer 160. As such, the amount of light emitted to the outside of the light-emitting chip 120 may be increased. The resin layer 160 may not necessarily fill the inner space of the package housing 140 as illustrated in FIG. 1. In other words, the resin layer 160 may be formed in a portion of the inner space to cover the light-emitting chip 120 and/or the submount 130.

The phosphor layer 180 may include a fluorescent material, for example, a resin-based material mixed with a fluorescent material. Light incident on the phosphor layer 180 may transmit energy to the fluorescent material. The color of the light may be converted to a color of light having low energy (e.g., light having a long wavelength). The light may then be emitted to the outside of the LED module 100.

The concentration of the fluorescent material of the phosphor layer 180 may be inhomogeneous. In other words, the concentration of the fluorescent material of the phosphor layer 180 may vary according to various portions of the phosphor layer 180. In addition, the thickness of the phosphor layer 180 may not be uniform. The concentration of the fluorescent material and/or the thickness distribution of the phosphor layer 180 may be determined based upon the condition of the bare chip (e.g., the radiation pattern of light emitted from the light-emitting chip 120 according to a previous coating of the phosphor layer 180). This kind of process may increase the phosphor conversion efficiency (PCE) by determining the concentration of the fluorescent material and/or the thickness of the phosphor layer 180 according to the intensity difference of the light incident on each part of the phosphor layer 180.

The PCE may be a ratio of the intensity of radiation to be emitted, which may be converted by the phosphor layer 180, to the intensity of radiation emitted from the light-emitting chip 120 when the phosphor layer 180 is not formed. As the PCE of the phosphor layer 180 increases, the brighter the LED module 100 may be. The radiation pattern of light emitted from the light-emitting chip 120 may vary due to the structure of the light-emitting chip 120 and the package housing 140. This is because the size of the inner space of the package housing 140 and/or the inner reflective surface 140a may be varied according to the package housing 140, and the size of the inner space of the package housing 140 and/or the inner reflective surface 140a may influence the radiation pattern of the light. Accordingly, the concentration of the fluorescent material of the phosphor layer 180 and/or the thickness of the phosphor layer 180 may be determined after measuring the radiation pattern of the light at the step of coating the phosphor layer 180. The concentration of the fluorescent material of the phosphor layer 180 and/or the thickness of the phosphor layer 180, in which the intensity of radiation may be higher, may be greater than that where the intensity of radiation may be lower.

A method of determining distributions of the concentration of the fluorescent material and the thickness of the phosphor layer 180 will be described in reference to FIGS. 2 through 7. However, example embodiments may not be limited to determining distributions of the concentration of the fluorescent material and the thickness of the phosphor layer 180 characteristics.

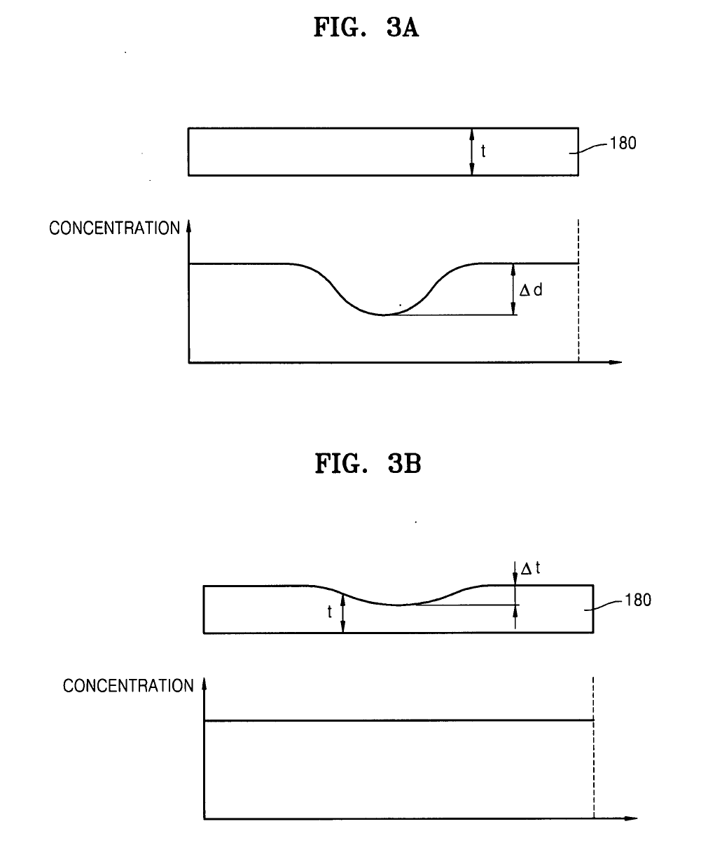

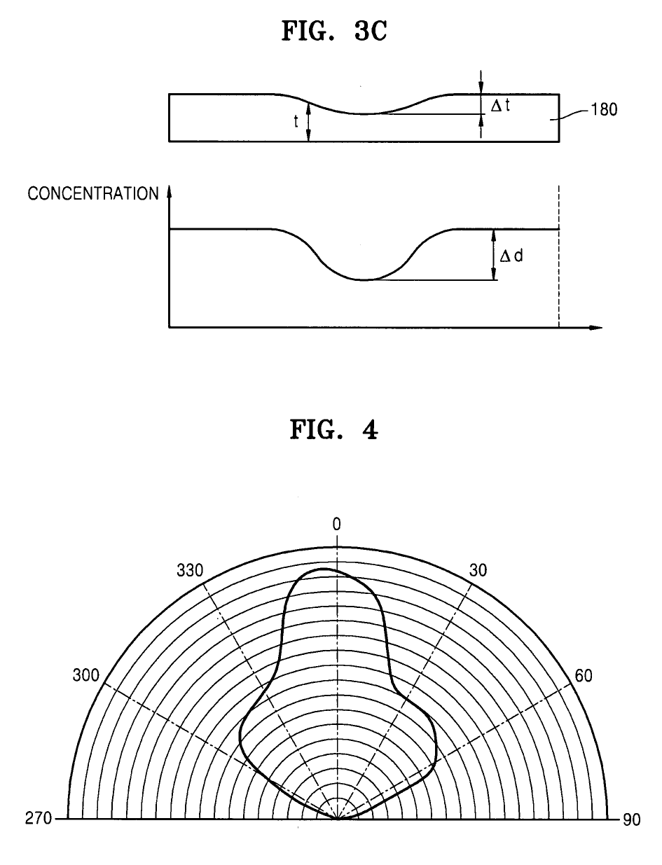

FIG. 2 is a graph of the radiation pattern of light emitted from the light-emitting chip 120, which may be measured at the step of coating the phosphor layer 180, according to example embodiments. FIGS. 3A through 3C illustrate a method of determining the concentration of the fluorescent material and the thickness of the phosphor layer 180 when the light-emitting chip 120 emits light having the radiation pattern of FIG. 2, according to example embodiments.

Referring to FIG. 2, the intensity of the radiation may be lower around the central axis. The intensity of radiation may reach a maximum value at about ±45° from the central axis and then, the intensity of radiation may decrease.

Referring to FIG. 3A, the thickness (t) of the phosphor layer 180 may be uniform. The concentration of the fluorescent material at the central portion of the phosphor layer 180, in which the intensity of radiation may be lower, may be lower. The concentration of the fluorescent material at the end portions of the phosphor layer 180, in which the intensity of radiation may be higher, may be higher. The variation of the concentration of the fluorescent material, Δd, may be determined according to the radiation characteristic with respect to the concentration of the fluorescent material, which will be described later.

FIG. 3B illustrates the thickness (t) of the phosphor layer 180 being varied. Referring to FIG. 3B, the concentration of the fluorescent material of the phosphor layer 180 may be uniform. The phosphor layer 180 may be formed to have a smaller thickness (t) at the central portion of the phosphor layer 180, in which the intensity of radiation may be lower. Near the end portions of the phosphor layer 180, in which the intensity of radiation may be higher, the thickness (t) of the phosphor layer 180 may be greater. The variation of the thickness of the phosphor layer 180, Δt, may be determined according to the radiation characteristic with respect to the thickness of the phosphor layer 180, which will be described later.

FIG. 3C illustrates the thickness (t) and the concentration of the fluorescent material being varied. Referring to FIG. 3C, the concentration of the fluorescent material of the phosphor layer 180 may be higher and the thickness of the phosphor layer 180 may be greater near the end portions of the phosphor layer 180. Accordingly, when the concentration and the thickness vary, the variation of the radiation characteristic may be greater, even when Δt or Δd is smaller, than that when only one factor varies. When the variation of the concentration or the thickness is not sufficient, the concentration of the fluorescent material and the thickness of the phosphor 180 may be varied in the above manner. In addition, when it is harder to control the radiation characteristic using only one factor, the concentration of the fluorescent material and the thickness of the phosphor layer 180 may be varied in the above manner.

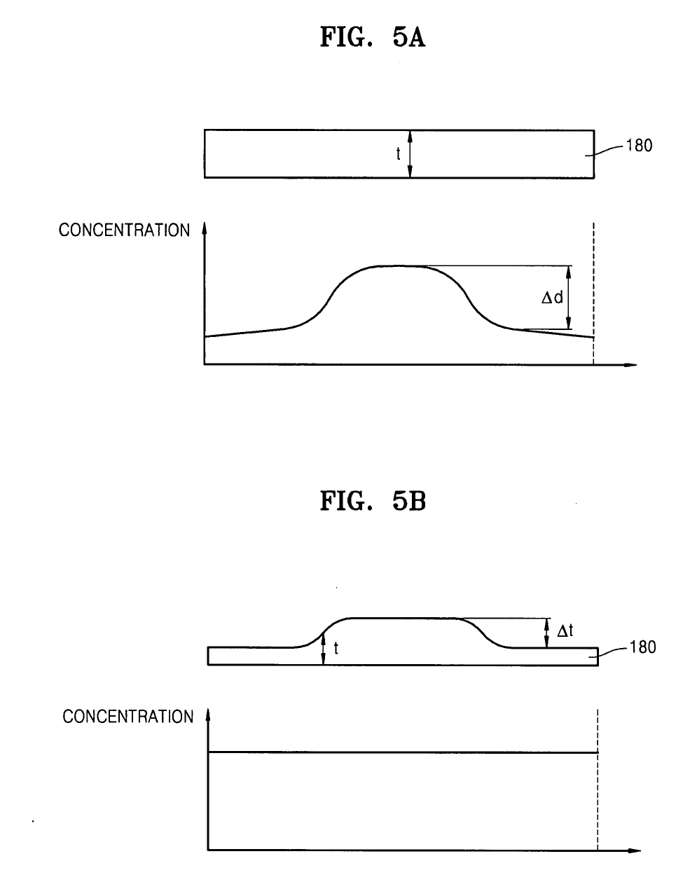

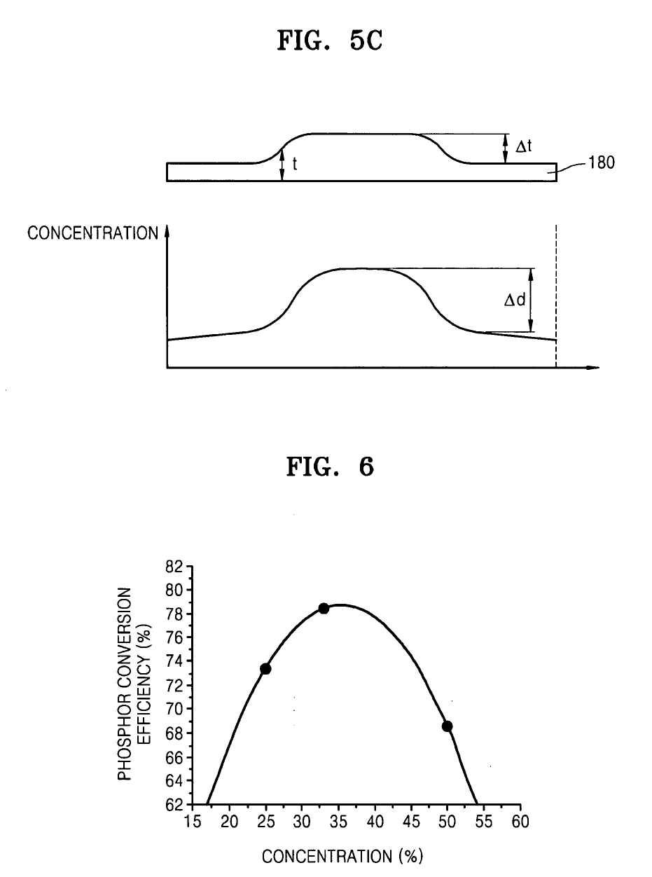

FIG. 4 is a graph of the radiation pattern of light emitted from the light-emitting chip 120 according to example embodiments, which may be measured at the step of coating the phosphor layer 180. FIGS. 5A through 5C illustrate a method of determining the concentration of the fluorescent material and the thickness of the phosphor layer 180 when the light-emitting chip 120 emits light having the radiation pattern of FIG. 4, according to example embodiments.

Referring to FIG. 4, the intensity of radiation may reach a peak around the central axis. The intensity of radiation may decrease in a direction away from the central axis.

Referring to FIG. 5A, the thickness (t) of the phosphor layer 180 may be uniform. The concentration of the fluorescent material may be higher at the central portion of the phosphor layer 180. On the other hand, the concentration of the fluorescent material may be lower at the end portions of the phosphor layer 180. The variation of the concentration of the fluorescent material is represented by Δd.

Referring to FIG. 5B, the concentration of the fluorescent material of the phosphor layer 180 may be uniform. The phosphor layer 180 may be formed to have a larger thickness (t) at the central portion of the phosphor layer 180. The variation of the thickness of the phosphor layer 180 is represented by Δt. Away from the central portion of the phosphor layer 180, the thickness (t) of the phosphor layer 180 may be smaller.

Referring to FIG. 5C, both the concentration of the fluorescent material and the thickness of the phosphor layer 180 may not be uniform, but both may have desired, or alternatively, predetermined distributions. The concentration of the fluorescent material and the thickness (t) of the phosphor layer 180 may be greater towards the central portion of the phosphor layer 180.

The concentration of the fluorescent material and/or the thickness of the phosphor layer 180 may vary as illustrated in FIGS. 3A to 3C and 5A to 5C. However, example embodiments may not be limited to the examples illustrated in FIGS. 3A to 3C and 5A to 5C. The distribution of the concentration and/or the thickness of the phosphor layer 180 may be a step function. The phosphor layer 180 may be divided into a plurality of parts each having a different concentration of the fluorescent material and/or a different thickness.

As the concentrations of the fluorescent material and/or the thicknesses of the phosphor layer 180 increase, the PCE of the phosphor layer 180 may not necessarily improve. At more than a predetermined or given variation of the concentration of the fluorescent material and/or the thickness of the phosphor layer 180, the PCE may be decreased, and thus the lighting characteristic may be decreased. Accordingly, distributions of the concentration of the fluorescent material and/or the thickness of the phosphor layer 180 may be determined according to the above.

FIG. 6 is a graph illustrating the PCE according to the concentration of a fluorescent material according to example embodiments.

The graph of FIG. 6 illustrates the PCE measured with respect to a white LED manufactured when the thickness of the phosphor layer including red, green, and blue fluorescent materials is about 200 μm and the concentration of the fluorescent material varies. When the concentration of the fluorescent material is more than about 35%, the PCE may not increase, but decrease. The concentration of the fluorescent material may vary according to the structure of the light-emitting chip and/or the package housing.

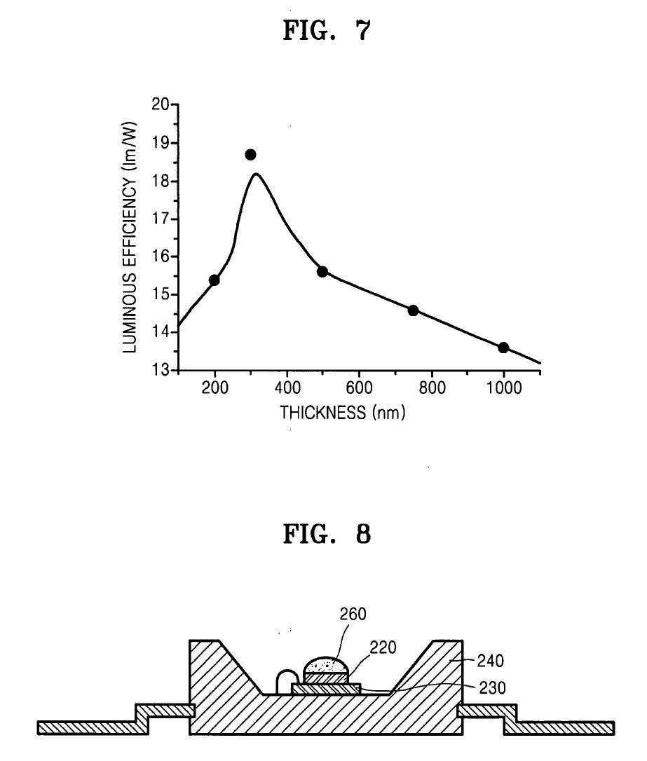

FIG. 7 is a graph illustrating the luminous efficiency according to the thickness of the phosphor layer, according to example embodiments.

The graph of FIG. 7 illustrates the luminous efficiency of a single color LED module manufactured when the concentration of the fluorescent material of the phosphor layer is about 40% and the thickness of the phosphor layer varies. The luminous efficiency may be one of the factors for determining the performance of the LED module and may be the brightness (lumen: lm) sensed by human eyes per supplied power of about 1 watt. As the thickness of the phosphor layer increases, the luminous efficiency may increase for thicknesses up to about 300 μm. However, the luminous efficiency may be lower for thicknesses greater than about 300 μm. Accordingly, the variation of the thickness of the phosphor layer may be determined according to the above. The thickness may vary according to the structure of the light-emitting chip and/or package housing.

Characteristics of a LED module manufactured according to the above description will now be described in comparison to a comparative LED module in reference to FIGS. 8 through 12.

FIG. 8 is a cross-sectional view illustrating a LED module when the radiation pattern of a light-emitting chip 220 is measured according to example embodiments. A submount 230 may be formed in the inner space of a package housing 240. The light-emitting chip 220 may be formed on the submount 230. A resin layer 260 may be formed on the light-emitting chip 220. The light-emitting chip 220 may emit light having a wavelength of about 410 nm.

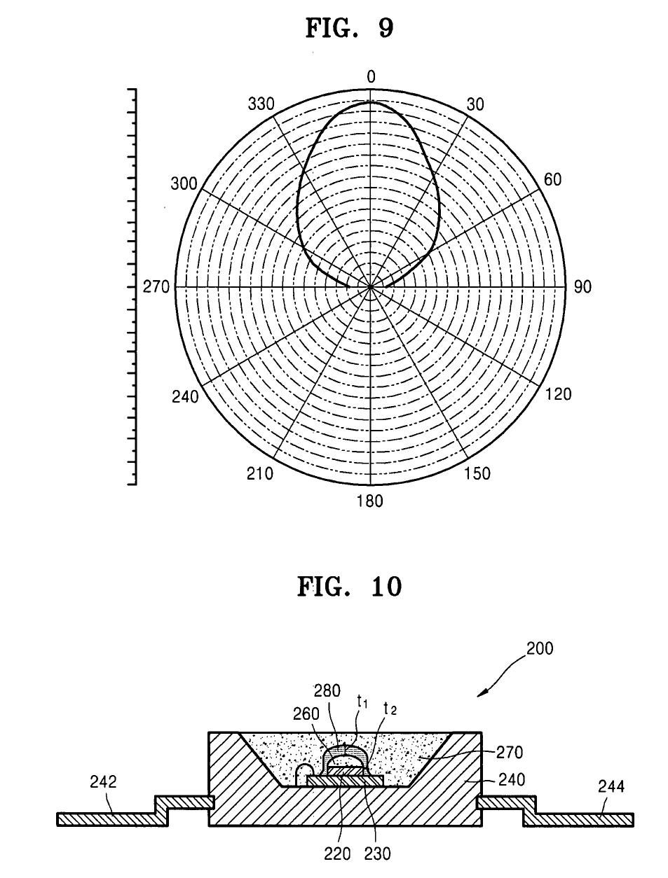

FIG. 9 is a graph illustrating the radiation pattern of the light-emitting chip 220 according to example embodiments. Referring to FIG. 9, the intensity of radiation may be greater on the central axis. The intensity of radiation may decrease in a direction away from the central axis.

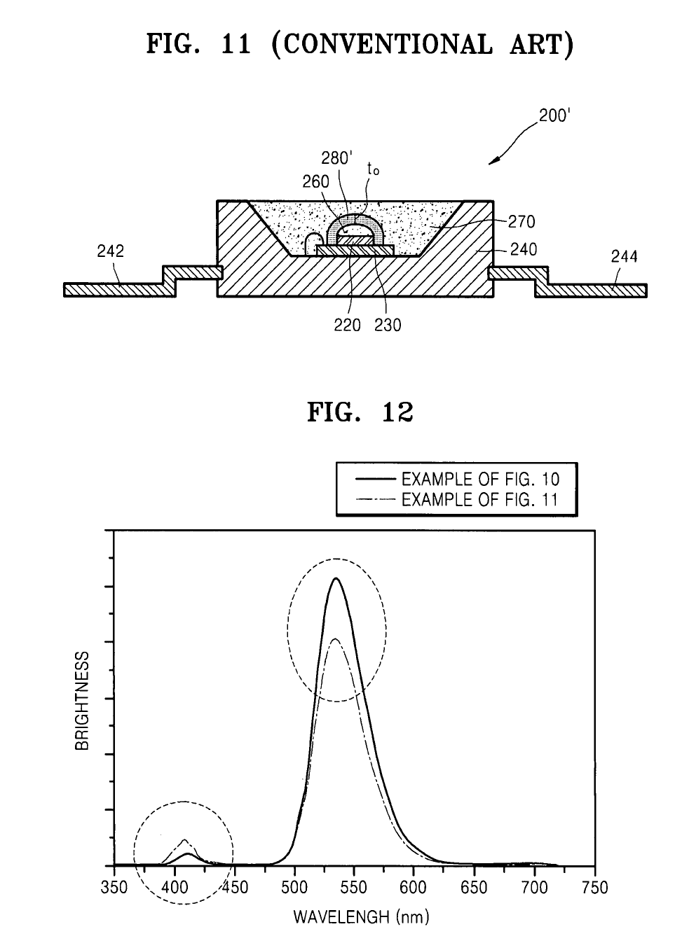

FIG. 10 is a cross-sectional view of a LED module 200 manufactured by coating a phosphor layer 280 having a varying thickness according to example embodiments. The LED module 200 may include the phosphor layer 280 on a light-emitting chip 220. The light-emitting chip 220 may be on a submount 230 formed on the bottom surface of the inner space of a package housing 240. A first lead frame 242 and a second lead frame 244, through which a voltage may be applied to the light-emitting chip 220, may be formed on the lower portion of the package housing 240. A resin layer 260 may be formed between the light-emitting chip 220 and the phosphor layer 280. A resin layer 270 may fill the inner space of the package housing 240. The thickness of the phosphor layer 280 may vary. The thickness of the central portion of the phosphor layer 280, of which the intensity of radiation may be higher, may be larger than that of the end portions of the phosphor layer 280, of which the intensity of radiation may be lower. The thicker the phosphor layer 280 is, the lower the PCE may be. Thus, according to example embodiments, the larger thickness t1 of the phosphor layer 280 may be about 300 nm and the smaller thickness t2 of the phosphor layer 280 may be about 50 nm.

FIG. 11 is a cross-sectional view of a LED module 200′ for comparison to a LED module of example embodiments. The structure of the LED module 200′ of FIG. 11 may be similar to that of the LED module 200 of FIG. 10 with the exception of the thickness of the phosphor layer 280. The thickness of the phosphor layer 280′ of the LED module 200′ of FIG. 11 may be uniform and may be about 200 nm.

FIG. 12 is a graph comparing the characteristics of the LED module 200 of FIG. 10 to that of the LED module 200′ of FIG. 11. Referring to FIG. 12, light to be emitted, which is converted by the phosphor layers 280 and 280,′ may have a greater intensity of radiation at a wavelength of about 535 nm. The intensity of the LED module 200 of FIG. 10 may be greater than that of the LED module 200′ of FIG. 11 by about 26%. In addition, because light having an undesired wavelength may be decreased in the LED module 200′ of FIG. 11, the PCE of the phosphor layer 280 of FIG. 10 may be increased or maximized.

As described above, a LED module including a light-emitting chip may be formed to have a desired, or alternatively, a predetermined thickness and/or concentration according to the radiation pattern of the light-emitting chip. As such, the LED module may have an improved brightness. In the method of manufacturing the LED module, the concentration of the fluorescent material of the phosphor layer and/or the thickness of the phosphor layer may be determined after measuring the radiation pattern of the light when the phosphor layer is not formed. Thus, a LED module may be manufactured to have improved brightness. In addition, the concentration and/or the thickness of the phosphor layer may be determined by measuring the PCE according to the concentration and/or the thickness of the phosphor layer based upon the radiation pattern. Thus, a LED module having improved light emitting characteristics and/or brightness may be manufactured.

Although example embodiments have been shown and described in this specification and figures, it would be appreciated by those skilled in the art that changes may be made to the illustrated and/or described example embodiments without departing from their principles and spirit.

What is claimed is:

1. A light emitting diode (LED) module comprising:
a package housing including an inner space;
a light-emitting chip in the inner space of the package housing; and
a phosphor layer including a fluorescent material and converting light emitted from the light-emitting chip to light having a longer wavelength than that of the light emitted from the light-emitting chip, wherein the concentration of the fluorescent material of the phosphor layer is inhomogeneous.

2. The LED module of claim 1, wherein the concentration of the fluorescent material of the phosphor layer is determined according to a radiation pattern of the light emitted from the light-emitting chip.

3. The LED module of claim 2, wherein the concentration of the fluorescent material of the phosphor layer is greater in the portions of the phosphor layer having a higher intensity of radiation than the portions of the phosphor layer having a lower intensity of radiation.

4. The LED module of claim 1, wherein the thickness of the phosphor layer is non-uniform.

5. The LED module of claim 4, wherein the thickness of the phosphor layer is determined according to the radiation pattern of the light emitted from the light-emitting chip.

6. The LED module of claim 5, wherein the portions of the phosphor layer having a higher intensity of radiation are thicker than the portions of the phosphor layer having a lower intensity of radiation.

7. A method of manufacturing a LED module, comprising:
providing a package housing having an inner space and including a light-emitting chip in the inner space;
measuring a radiation pattern of light emitted from the light-emitting chip in the inner space of the package housing; and
forming a phosphor layer including a fluorescent material on the light-emitting chip, wherein a characteristic of the phosphor layer including the fluorescent material is determined according to the radiation pattern.

8. The method of claim 7, wherein the thickness of the phosphor layer including the fluorescent material is the characteristic being determined such that the portions of the phosphor layer having a higher intensity of radiation are thicker than the portions of the phosphor layer having a lower intensity of radiation.

9. The method of claim 8, wherein luminous efficiency or phosphor conversion efficiency (PCE) is measured according to the thickness of the phosphor layer with respect to the light-emitting chip in the inner space of the package housing.

10. The method of claim 9, wherein the greater the luminous efficiency or the PCE is, the thicker the phosphor layer is.

11. The method of claim 8, wherein the thickness of the phosphor layer is non-uniform.

12. The method of claim 7, wherein the concentration of the fluorescent material of the phosphor layer is the characteristic being determined such that the concentration of the fluorescent material of the phosphor layer is greater in the portions of the phosphor layer having a higher intensity of radiation than the portions of the phosphor layer having a lower intensity of radiation.

13. The method of claim 12, wherein luminous efficiency or PCE is measured according to the concentration of the fluorescent material of the phosphor layer with respect to the light-emitting chip in the inner space of the package housing.

14. The method of claim 13, wherein the greater the concentration of the fluorescent material of the phosphor layer is, the greater the luminous efficiency or the PCE is.
